(19) United States
(12) Patent Application Publication
(10) Pub. No.: US 2012/0281372 A1
(43) Pub. Date: Nov. 8, 2012

(54) BOARD ATTACHMENT STRUCTURE AND ELECTRIC DEVICE

(75) Inventor: Naoto MARUTA, Osaka (JP)

(73) Assignee: Funai Electric Co., Ltd., Osaka (JP)

(21) Appl. No.: 13/448,662

(22) Filed: Apr. 17, 2012

(30) Foreign Application Priority Data
May 8, 2011 (JP) 2011-103379

(51) Int. Cl. H05K 7/00; H05K 5/00; H05K 7/18

(52) U.S. Cl. 361/752; 211/26.2; 361/748

(57) ABSTRACT

A board attachment structure includes a frame, a plurality of board holders and a plurality of engagement mechanisms. The board holders are detachably coupled to the frame. The board holders are configured to hold a circuit board between a pair of adjacent board holders of the board holders. The adjacent board holders have mutually facing surfaces with grooves, respectively. The grooves of the adjacent board holders are configured to support opposite edge portions of the circuit board, respectively, when the board holders hold the circuit board. The engagement mechanisms detachably couple the board holders to the frame, respectively. The engagement mechanisms have engagement holes that are provided to the frame and hooks that are disposed on the board holders. The hooks of the board holders are detachably engaged with the engagement holes of the frame, respectively.

### CROSS-REFERENCE TO RELATED APPLICATIONS

This application claims priority to Japanese Patent Application No. 2011-103379 filed on May 6, 2011. The entire disclosure of Japanese Patent Application No. 2011-103379 is hereby incorporated herein by reference.

### BACKGROUND

1. Field of the Invention

The present invention generally relates to a board attachment structure. More specifically, the present invention relates to a board attachment structure for attaching a board to a frame.

2. Background Information

A conventional board attachment structure is disposed in a liquid crystal television receiver. The board attachment structure has a flat, sheet metal frame with bulges, and a rectangular board. The board is attached to the frame. The frame is equipped with an image display module, such as a liquid crystal module, on its rear. The bulges are formed by drawing substantially in the form of a truncated cone at a plurality of locations on the flat part of the frame. Threaded holes are provided in the tops of these bulges, respectively. Attachment screw inserting holes are formed in the four corners of the board. The four corners of the board rest on the tops of the bulges on the frame. In this state, attachment screws are inserted into the attachment screw inserting holes in the four corners of the board, and are threaded into the threaded holes of the four bulges.

Another conventional structure has been proposed in which bending tabs are formed at four places on a panel fixing plate of an LCD television set (see Japanese Laid-Open Patent Application Publication No. 2007-116556, for example). A board was sandwiched between these bending tabs and the panel fixing plate, thereby attaching the board to the panel fixing plate.

Further another conventional structure has been proposed in which a board is screwed to a base formed by cutting and lifting a sheet metal shield panel. The board is positioned in two mutually perpendicular axial directions by two protrusions provided to this base (see Japanese Laid-Open Patent Application Publication No. 2008-218845, for example).

Yet another conventional structure has been proposed to prevent the loss of operability of switch parts mounted on a printed board even when frame members of the same type are shared by printed boards of different specifications (see Japanese Laid-Open Patent Application Publication No. 2002-314271, for example).

Further another conventional structure has been proposed for sharing digital boards in a display device (see Japanese Laid-Open Patent Application Publication No. 2010-261995, for example).

### SUMMARY

With the conventional board attachment structure, if the specifications of the boards, and more specifically, the sizes of the boards, varies due to the region of intended use or various other factors, then the specifications of the frame that allows the four corners of the boards to be screwed down will also have to be changed to match the specifications of the boards. Because of this, with the board attachment structure, the frame cannot be shared by boards with different specifications (e.g., sizes). This entails higher costs for producing molds and so forth to produce frames for attaching boards with different specifications. As a result, the liquid crystal television receiver having the board attachment structure ends up costing more to produce.

Also, with the conventional board attachment structure, the board needs to be screwed down at multiple locations. Furthermore, if the attachment screws are repeatedly installed in and removed from the threaded holes provided to the tops of the bulges in the frame, the function of these threaded holes may be lost, resulting in what is known as a “stripped hole,” and making it impossible to tighten the attachment screws at these locations.

Meanwhile, with another conventional structure described above, the board can be attached to a panel fixing plate without being screwed down. However, since the locations where the bending tabs are formed have to be varied according to the sizes of the boards, the panel fixing plate cannot be shared by boards with different specifications. Also, with above-mentioned conventional structures, effective ways for a frame to which boards are attached to be shared by boards of different sizes are not proposed.

An improved board attachment structure was conceived in light of the above-mentioned problem. One object of the present disclosure is to provide a board attachment structure with which one type of frame can be shared by boards of different sizes.

Another object of the present disclosure is to provide a board attachment structure with which boards can be attached to a frame without being screwed down.

In accordance with one aspect of the present disclosure, a board attachment structure includes a frame, a plurality of board holders and a plurality of engagement mechanisms. The board holders are detachably coupled to the frame. The board holders are configured to hold a circuit board between a pair of adjacent board holders of the board holders. The adjacent board holders are spaced apart from each other with a predetermined spacing therebetween. The adjacent board holders have mutually facing surfaces with grooves, respectively. The grooves of the adjacent board holders extend in a lengthwise direction of the adjacent board holders. The grooves of the adjacent board holders are configured to support opposite edge portions of the circuit board, respectively, when the board holders hold the circuit board. The engagement mechanisms detachably couple the board holders to the frame, respectively. The engagement mechanisms have engagement holes that are provided to the frame and hooks that are disposed on the board holders. The hooks of the board holders are detachably engaged with the engagement holes of the frame, respectively

These and other objects, features, aspects and advantages will become apparent to those skilled in the art from the following detailed description, which, taken in conjunction with the annexed drawings, discloses a preferred embodiment.

### BRIEF DESCRIPTION OF THE DRAWINGS

Referring now to the attached drawings which form a part of this original disclosure:

FIG. 1 is a front elevational view of a board attachment structure in accordance with one embodiment;

FIG. 2 is a partial side elevational view of the board attachment structure illustrated in FIG. 1, illustrating a cross section of a frame of the board attachment structure taken along II-II line in FIG. 1;

FIG. 3 is an exploded perspective view of the board attachment structure illustrated in FIG. 1, illustrating an attachment of a board to a board holder of the board attachment structure;

FIG. 4 is a partial front elevational view of the board attachment structure illustrated in FIG. 1, illustrating an attachment procedure for attaching the board to the board holder;

FIG. 5 is a front elevational view of the frame of the board attachment structure illustrated in FIG. 1;

FIG. 6 is an enlarged view of an engagement mechanism of the frame illustrated in FIG. 5;

FIG. 7 is an enlarged cross sectional view of the engagement mechanism of the frame taken along VII-VII line in FIG. 6;

FIG. 8 is an enlarged, partial side elevational view of the board attachment structure illustrated in FIG. 1, illustrating a portion VIII in FIG. 2;

FIG. 9 is an enlarged, partial front elevational view of the board attachment structure illustrated in FIG. 1, illustrating an attachment procedure for attaching the board holder to the frame;

FIG. 10 is an enlarged, partial front elevational view of the board attachment structure illustrated in FIG. 1, with a portion of the board holder broken away to show how the board and the board holder fit together; and

FIG. 11 is a front elevational view of the board attachment structure illustrated in FIG. 1, illustrating an attachment of boards with different lengths to the board holder of the board attachment structure.

### DETAILED DESCRIPTION OF EMBODIMENTS

A preferred embodiment will now be explained with reference to the drawings. It will be apparent to those skilled in the art from these disclosures that the following descriptions of the preferred embodiment are provided for illustration only and not for the purpose of limiting the invention as defined by the appended claims and their equivalents.

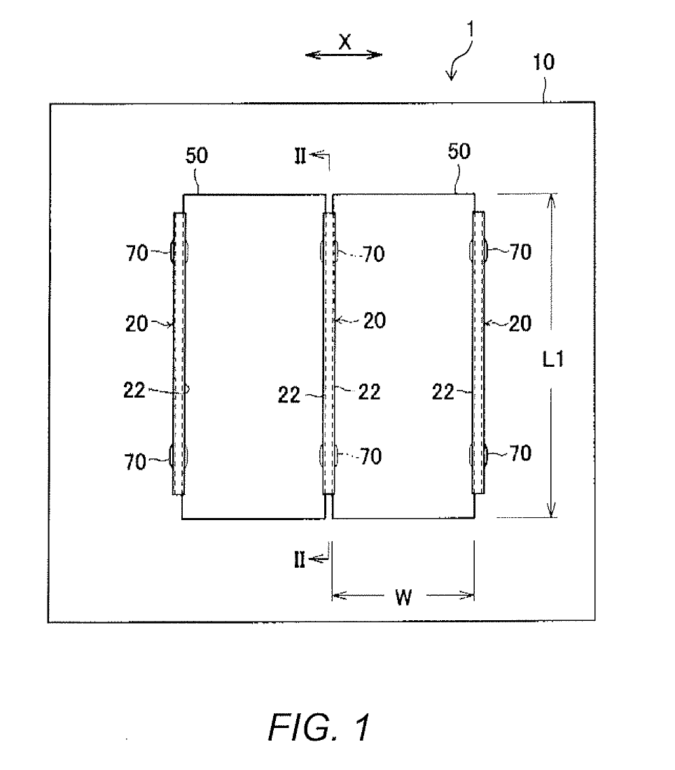

Referring to FIGS. 1 to 11, a board attachment structure (or device board attachment structure) will be described. The board attachment structure is installed in a liquid crystal television receiver (e.g., an electrical or electronic device). The board attachment structure basically includes a flat frame 10 with a plurality of (two in FIG. 1) boards 50 (e.g., circuit boards). The boards 50 are attached to the frame 10. The frame 10 is made of sheet metal. The frame 10 is a sheet metal chassis disposed at a rear portion of the liquid crystal module 1 (e.g., an image display module). The liquid crystal module 1 further has a liquid crystal panel (not shown) disposed in the frame 10, and a bezel (not shown) attached to the frame 10. The liquid crystal module 1 is installed in the liquid crystal television receiver. The liquid crystal module 1 and the liquid crystal television receiver can further include well-known conventional arrangements. However, since these arrangements are conventional, the description will be omitted for the sake of brevity. The boards 50 include a power circuit board, a digital circuit board, an audio circuit board, and so forth that are attached to the frame 10 which forms the chassis of the liquid crystal module 1.

As shown in FIG. 1, the board attachment structure further includes a plurality of (three in FIG. 1) board holders 20. Each of the board holders 20 is integrally formed as a one-piece, unitary member. The board holders 20 are detachably coupled to the frame 10 at a plurality of (three in FIG. 1) locations that are equidistantly spaced apart in a lateral direction X of the frame 10. The spacing (e.g., predetermined spacing) between a pair of adjacent board holders 20 is established by or corresponds to the width W of the boards 50 that are held by these board holders 20. In particular, the spacing between the adjacent board holders 20 is dimensioned according to the width W of the boards 50. As shown in FIG. 1, the board holder 20 that is located in the middle and the board holder 20 located to the far left side are used to hold the board 50 (e.g., circuit board) on the left side, while the board holder 20 located in the middle and the board holder 20 located to the far right side are used to hold the board 50 (e.g., additional circuit board) on the right side. The width W of the left and right boards 50 measured in a widthwise direction that is parallel to the lateral direction X of the frame 10 is the same. The lengths F1 thereof measured in a lengthwise direction that is perpendicular to the lateral direction X of the frame 10 are also the same. One of these two boards 50 corresponds to a power circuit board, for example, and the other corresponds to a digital circuit board, for example, The boards 50 are electrically connected to the liquid crystal panel disposed in the frame 10.

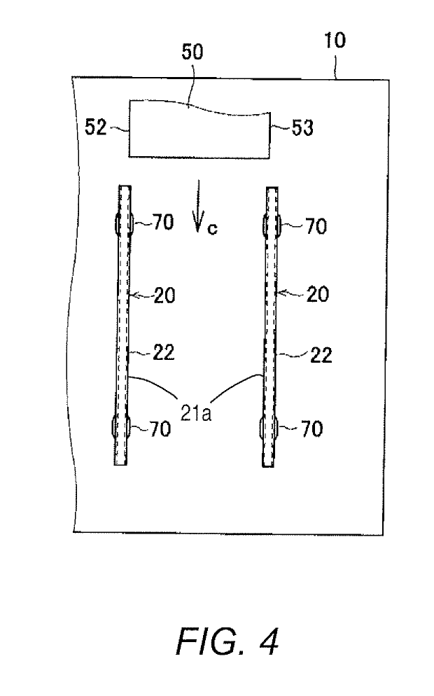

The board holders 20 fixed to the frame 10 are resin moldings. The board holders 20 are identical to each other. As shown in FIG. 3, the board holders 20 each have a core 21 (e.g., slender core member) and two grooves 22 (e.g., groove components or groove-shaped components). The core 21 has a symmetrical shape relative to a center axis of the core 21. The grooves 22 have a symmetrical shape and are provided on both opposite side faces 21a of this core 21. The groove width of these grooves 22 is substantially equal to the thickness of the boards 50. As shown in FIG. 3, a left edge portion 52 (e.g., opposite edge portion) on one side (or left side) of one of the boards 50 is fitted into one of the grooves 22 on one side (or right side) by pushing the board 50 into this groove 22 in the direction of arrow a. Furthermore, a right edge portion 53 (e.g., opposite edge portion) on the other side (or right side) of the other of the boards 50 is fitted into the other of the grooves 22 on the other side (or left side) by pushing this board 50 into the groove 22 in the direction of arrow b. Also, as shown in FIG. 4, both edge portions 52 and 53 of one of the boards 50 can be fitted into and supported by the opposite grooves 22 formed on mutually facing surfaces 21a of the adjacent board holders 20. Specifically, the board 50 can be fitted into the opposite grooves 22 by pushing this board 50 in the direction of the arrow c from ends of opposite grooves 22. At the places where the boards 50 are fitted into the grooves 22, enough fitting precision is ensured such that there will be no looseness of the boards 50 in a groove width direction. Furthermore, enough fitting precision is ensured such that there will be no looseness of the boards 50 in the lateral direction X of the frame 10.

The core 21 and the grooves 22 of each of the board holders 20 extend in a lengthwise direction of each board holder 20 over the entire length of the board holder 20. Therefore, when the edge portions of the boards 50 are fitted into the grooves 22 of the board holders 20 as shown in FIG. 1, an advantage is that warping in the lengthwise direction of the boards 50 is suppressed at these fitting locations.

As shown in FIG. 1, the two boards 50 have the same width W and the same length L1. However, the two boards 50 can have different lengths, as long as their width W is substantially the same. As shown in FIG. 11, the frame 10 and the three board holders 20 are the same as those shown in FIG. 1. The two boards 50 shown in FIG. 11 have the same width W as the boards 50 shown in FIG. 1. However, the board 50 located on the right side in FIG. 11 has a length L2 that is greater than the length L1 of the board 50 in FIG. 1, and the board 50 located on the left side in FIG. 11 has a length L3 that is less than the length L1 of the board 50 in FIG. 1. As can be seen by a comparison of FIGS. 1 and 11, as long as the boards 50 have the same width W, a single type of frame 10 of a given size can be shared by the various boards 50 even though their lengths are different from each other.

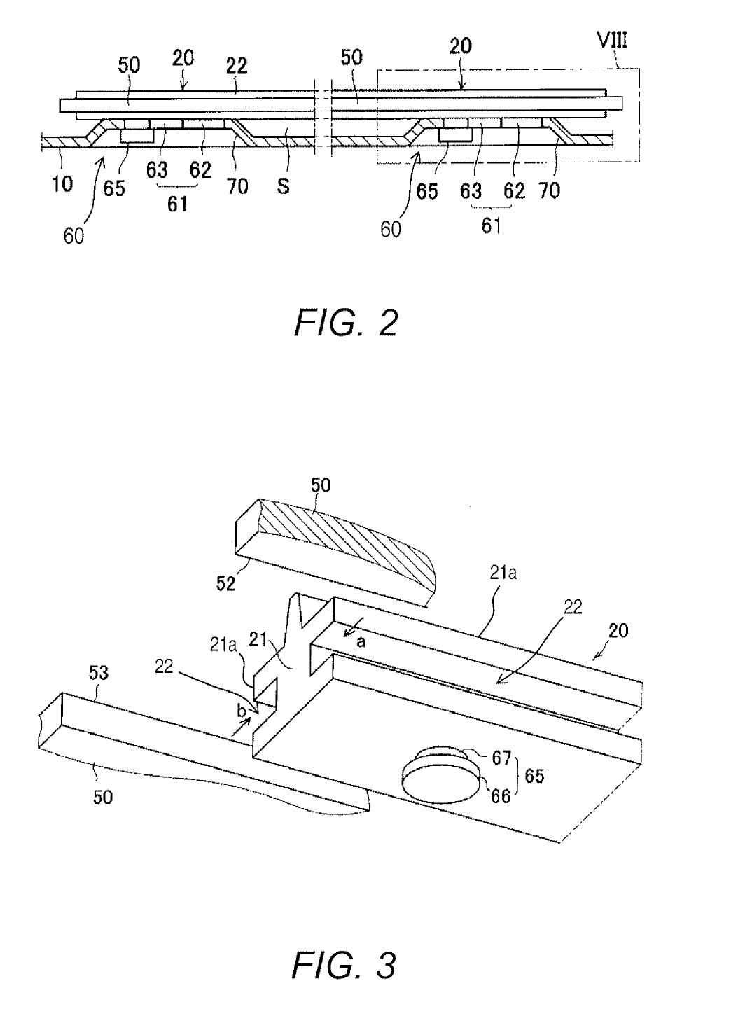

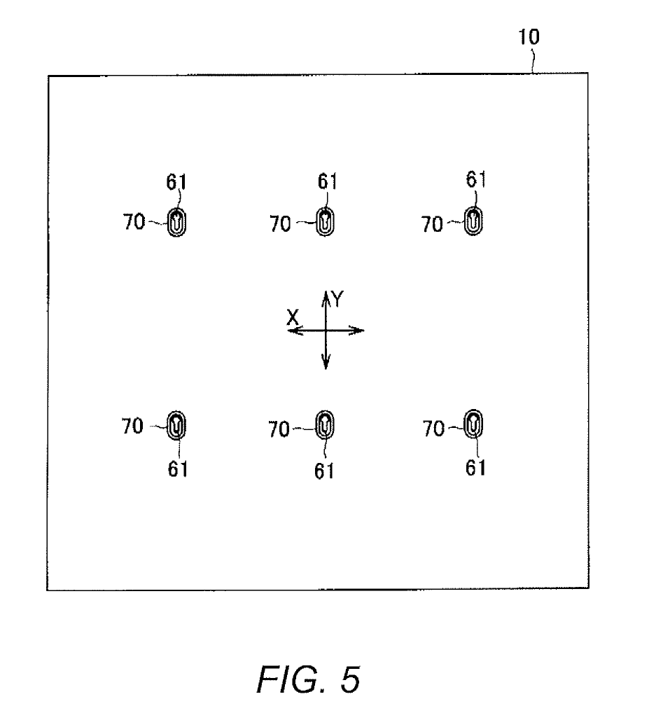

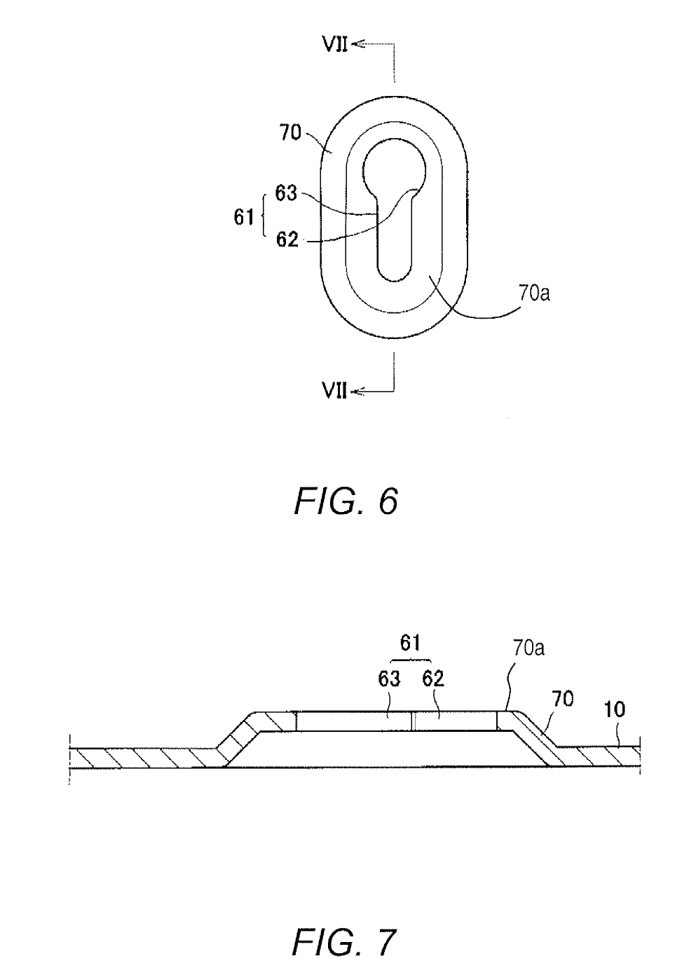

As shown in FIG. 2, the board attachment structure further includes a plurality of engagement mechanisms 60. The engagement mechanisms 60 detachably couple the board holders 20 to the frame 10, respectively. These engagement mechanisms 60 each have a bulge 70 (e.g., bulge portion) with an engagement hole 61, and a hook 65. As shown in FIG. 5, three pairs of bulges 70 are formed on a rear plate of the frame 1. Furthermore, the engagement holes 61 are formed on top faces 70a of the bulges 70 of the frame 10, respectively. The hooks 65 are molded from resin integrally with the board holders 20, respectively. In particular, each of the board holders 20 has two hooks 65 on a lower face of each of the board holders 20. The hooks 65 are removably engaged with the engagement holes 61, respectively. As shown in FIG. 6, each of the engagement holes 61 is formed in a keyhole shape, and has a circular hole component 62 and a slot component 63 that is narrower in width and communicates with this circular hole component 62. On the other hand, as shown in FIG. 3, each of the hooks 65 has a circular flange 66 and a leg component 67. The circular flanges 66 have a size that allow them to pass through the circular hole components 62 of the engagement holes 61, respectively. The leg components 67 link the flanges 66 with lower faces of the board holders 20, respectively. The leg components 67 have a thickness or diameter that allows them to pass through the narrow slot components 63, respectively. As shown in FIG. 2, the hooks 65 are provided at two locations of a single board holder 20 in the lengthwise direction thereof.

As shown in FIG. 5, the engagement holes 61 are aligned in a vertical direction Y perpendicular to the lateral direction X and in the lateral direction X. Three pairs of engagement holes 61 are provided to the frame 10 at three locations equidistantly spaced apart in the lateral direction X. More specifically, the pairs of engagement holes 61 are separated at a spacing that corresponds to the width W of the boards 50 such that the adjacent board holders 20 is spaced apart from each other with a predetermined spacing therebetween that corresponds to the width W of the boards 50. A single board holder 20 can be fixed to the frame 10 by utilizing two of these engagement holes 61 that are aligned in the vertical direction Y.

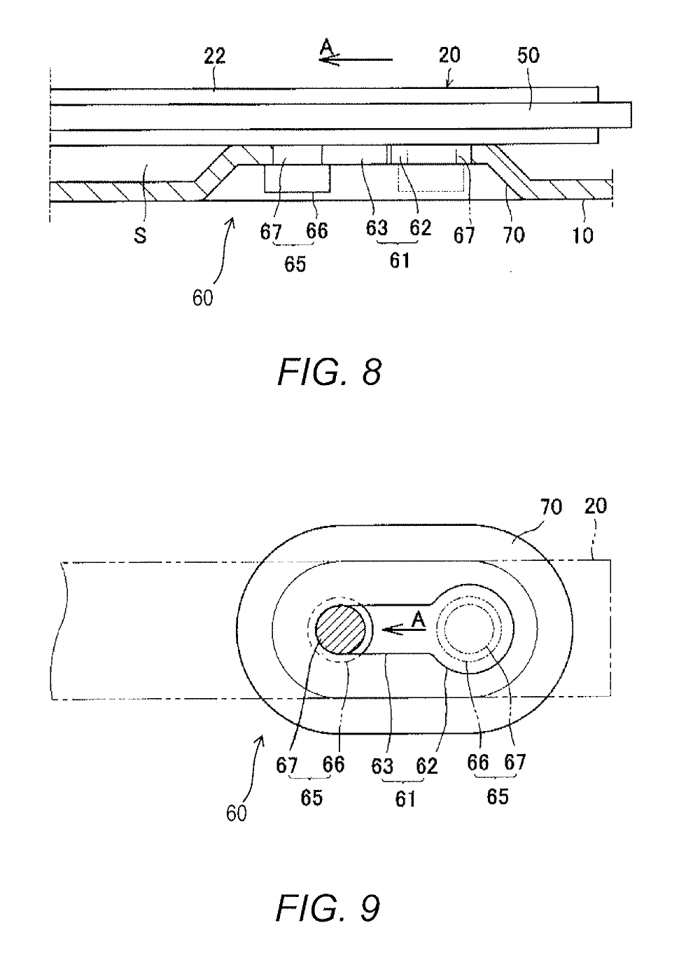

Referring to FIGS. 8 and 9, an attachment procedure for fixing each of the board holders 20 to the frame 10 using the engagement mechanisms 60 will be described. At the initial stage, as shown by imaginary lines in FIGS. 8 and 9, the flanges 66 of the hooks 65 of the board holder 20 are inserted into the circular hole components 62 of the engagement holes 61. The leg components 67 of the hooks 65 face the slot components 63 of the engagement holes 61. Then, as indicated by an arrow A, the board holder 20 is slid in the lengthwise direction (i.e., the vertical direction Y in FIG. 5) to push the leg components 67 of the hooks 65 into the slot components 63 of the engagement holes 61. When this is done, the leg components 67 engage with edges of the slot components 63, which fixes the board holder 20 to the frame 10 without the use of any attachment screws. In terms of improving the fixing reliability, the spacing between the lower face of the board holder 20 and the flanges 66 of the hooks 65 is set to be about the same as the thickness of the portion of the frame 10 where the engagement holes 61 are formed. With this arrangement, the places where the engagement holes 61 are formed will be securely sandwiched between the flanges 66 and the board holder 20. The hooks 65 are provided at two places in the lengthwise direction of a single board holder 20. Since these hooks 65 are fixed in the engagement holes 61 at two places on the frame 10, a situation can not arise in which the board holder 20 that is fixed to the frame 10 via the engagement mechanisms 60 pivots using one of the hooks 65 as a fulcrum. When the hooks 65 are to be removed from the engagement holes 61, the above procedure is reversed.

As shown in FIGS. 5 and 7, the engagement holes 61 are formed in the tops of the bulges 70. The bulges 70 are in the form of a truncated cone and are formed by drawing at a plurality of (six in FIG. 5) locations on the frame 10. Accordingly, as shown in FIGS. 2 and 8, a gap S corresponding to the height of the bulges 70 is formed between the frame 10 and the boards 50 mounted on the board holders 20 that are fixed to the frame 10. This gap S serves as a space that prevents the terminal pins or circuit pattern on the boards 50, solder bumps, and the like from touching the sheet metal frame 10 and causing an electrical short. Also, this gap S serves as a space for accommodating the electrical and electronic parts mounted on the rear face of the boards 50.

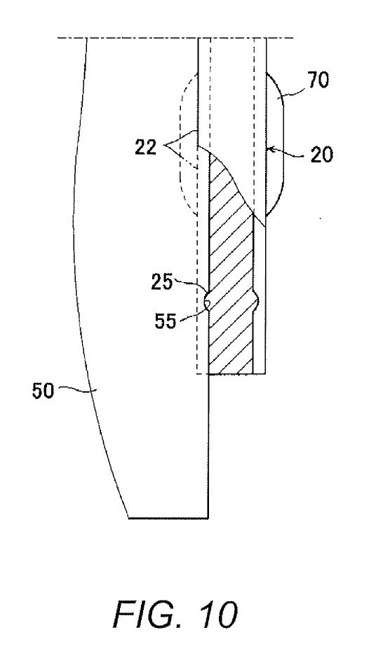

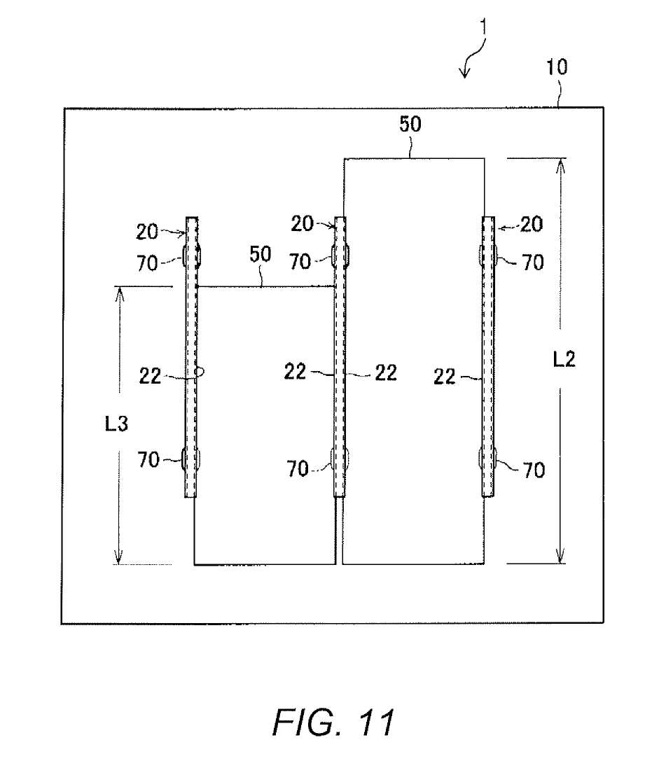

Furthermore, as shown in FIG. 10, the board attachment structure further includes an attachment mechanism to position the boards 50 in the lengthwise direction of the board holders 20. Specifically, as shown in FIG. 10, the attachment mechanism includes a plurality of concave components 55 and a plurality of convex components 25. The concave components 55 are formed in at least one of the left and right edge portions 52 and 53 of the boards 50. The convex components 25 are provided to the groove wall faces (more specifically, the groove bottom faces) of the grooves 22 of the board holders 20. The edges of the boards 50 are then fitted into the grooves 22 of the board holders 20, and the concave components 55 are mated to the convex components 25, respectively. When this is done, the concave components 55 engage with the convex components 25 in the lengthwise direction of the board holder 20, and the boards 50 are positioned in the lengthwise direction of the board holders 20. The concave components 55 can instead be formed in the groove wall faces of the grooves 22, and the convex components 25 on the left and right edge portions 52 and 53 of the boards 50.

With the board attachment structure, two boards 50 are mounted to three board holders 20 fixed at three equidistantly spaced locations on the frame 10. However, the configuration can instead be such that a single board is mounted on a pair of board holders fixed at two places on the frame 10, or such that three boards are mounted on four board holders fixed at four equidistantly spaced places on the frame 10.

The board attachment structure includes the flat frame 10, the board holders 20 to which the boards 50 are mounted, and the engagement mechanisms 60 for fixing the board holders 20 to the frame 10. The board holders 20, which are each formed by a slender resin molding, are fixed to the frame 10 at a plurality of locations that are separated at a spacing corresponding to the width W of the boards 50. The edges on the left and right sides in the width direction of each of the boards 50 are separately fitted into grooves 22 extending in the lengthwise direction and provided to a pair of adjacent board holders 20, The engagement mechanisms 60 that fix the board holders 20 to the frame 10 have the engagement holes 61 provided to the frame 10, and the hooks 65 that are integrally molded from resin on the board holders 20. The hooks 65 are removably engaged with the engagement holes 61.

With this arrangement, the board holders 20 are fixed to the flat frame 10 and separated at a spacing corresponding to the width W of the boards 50. Also, the edges on left and right sides in the width direction of each of the boards 50 are separately fitted into grooves 22 extending in the lengthwise direction and provided to a pair of adjacent board holders 20. Accordingly, as long as the widths W of the boards 50 remains constant, a single type of frame 10 of a given configuration can be shared by the boards 50 having different lengths.

Also, the engagement mechanisms 60 that fix the board holders 20 to the frame 10 have the engagement holes 61 provided to the frame 10, and the hooks 65 that are integrally molded from resin on the board holders 20 and are removably engaged with the engagement holes 61. Thus, no attachment screws are necessary as a means for attaching the boards 50 to the frame 10.

With the board attachment structure, it is preferable if the board holders 20 each have the core 21 and two of the grooves 22, which have a symmetrical shape and are provided on both sides of this core 21. With this arrangement, the edge portions 52 of the boards 50 on the left side in the width direction are fitted into the grooves 22 on one side of the board holders 20, respectively. The edge portions 53 of the boards 50 on the right side in the width direction are fitted into the grooves 22 on the other side of the board holders 20 with the same configuration. Thus, the board holders 20 used to mount a single board 50 can be identically formed. Therefore, it is possible to use a single type of board holders 20 of a given configuration to attach the boards 50 to the frame 10.

With the board attachment structure, it is preferable if the engagement holes 61 of the engagement mechanisms 60 are formed at the top faces 70a of the bulges 70 formed in the frame 10. With this arrangement, the gap S corresponding to the height of the bulges 70 is formed between the frame 10 and the boards 50 attached to the frame 10 via the board holders 20. Thus, this gap S can serve as a space that prevents the terminal pins or circuit pattern on the boards 50, solder bumps, and the like from touching the frame 10 and causing an electrical short.

With the board attachment structure, it is possible to employ a configuration in which the convex components 25 are formed on one side of either the edges of the boards 50 or the groove wall faces of the grooves 22 in the board holders 20 into which these edges of the boards 50 are fitted, and the concave components 55 that mate with the convex components 25 and are used for positioning the boards 50 in the lengthwise direction of the board holders 20 are formed on the other side. Employing this configuration allows for easy positioning of the boards 50 and the board holders 20 in the lengthwise direction of the boards 50 without having to use any screws or other such separate parts.

With the board attachment structure, it is possible to employ a configuration in which the frame 10 is a sheet metal chassis equipped with the liquid crystal module 1 on its rear. With this arrangement, if it should be necessary to attach a power circuit board, a digital circuit board, an audio circuit board, or any of various other kinds of board to the chassis, then as long as all of these boards 50 have the same width W, it will be possible to attach all the boards 50 to a single chassis, without the use of screws, even though the boards 50 are of different lengths.

As discussed above, with the board attachment structure, as long as there is a specific restriction on the width W of the boards 50, a single type of frame 10 with a given configuration can be shared by the boards 50 having different length specifications. Therefore, even if the specifications of the boards 50 varies due to the region of intended use or various other factors, production cost for molds and so forth for producing frames 10 can be kept low. Thus, liquid crystal television receivers and other such electrical or electronic devices can be offered that much less expensively. Also, since there is no need to use attachment screws to attach the boards 50 to the frame 10, the trouble involved in having to screw down the boards at multiple locations can be eliminated. Furthermore, the problem of screw holes turning into “stripped holes” does not occur.

### GENERAL INTERPRETATION OF TERMS

In understanding the scope of the present invention, the term “comprising” and its derivatives, as used herein, are intended to be open ended terms that specify the presence of the stated features, elements, components and groups, but do not exclude the presence of other unstated features, elements, components and groups, The foregoing also applies to words having similar meanings such as the terms, “including”, “having” and their derivatives. Also, the terms “part,” “section,” “portion,” “member” or “element” when used in the singular can have the dual meaning of a single part or a plurality of parts.

While a preferred embodiment has been chosen to illustrate the present invention, it will be apparent to those skilled in the art from these disclosures that various changes and modifications can be made herein without departing from the scope of the invention as defined in the appended claims. Furthermore, the foregoing descriptions of the embodiment according to the present invention are provided for illustration only, and not for the purpose of limiting the invention as defined by the appended claims and their equivalents.

What is claimed is:

1. A board attachment structure comprising:
a frame;
a plurality of board holders detachably coupled to the frame, the board holders being configured to hold a circuit board between a pair of adjacent board holders of the board holders, the adjacent board holders being spaced apart from each other with a predetermined spacing therebetween, the adjacent board holders having mutually facing surfaces with grooves, respectively, the grooves of the adjacent board holders extending in a lengthwise direction of the adjacent board holders, the grooves of the adjacent board holders being configured to support opposite edge portions of the circuit board, respectively, when the board holders hold the circuit board; and
a plurality of engagement mechanisms detachably coupling the board holders to the frame, respectively; the engagement mechanisms having engagement holes that are provided to the frame and hooks that are disposed on the board holders, the hooks of the board holders being detachably engaged with the engagement holes of the frame, respectively.

2. The board attachment structure according to claim 1, wherein
each of the board holders has a slender core member with a pair of groove components, the slender core member having a symmetrical shape relative to a center axis of the slender core member, the groove components being disposed in opposite side faces of the slender core member, respectively, at least one of the groove components forming one of the grooves of the adjacent board holders.

3. The board attachment structure according to claim 1, wherein
the frame further includes bulging portions with top faces, the engagement holes of the engagement mechanisms being disposed in the top faces of the bulging portions, respectively.

4. The board attachment structure according to claim 1, wherein
each the adjacent board holders includes one of a convex component and a concave component within each of the grooves of the adjacent board holders, the one of the convex component and the concave component being configured to engage with the other of the convex component and the concave component that is disposed on each of the opposite edge portions of the circuit board to position the circuit board relative to the adjacent board holders in the lengthwise direction of the adjacent board holders.

5. The board attachment structure according to claim 1, wherein
the frame is made of a sheet metal, the frame forming a rear chassis of an image display module.

6. The board attachment structure according to claim 1, wherein
the board holders and the hooks are made of resin, the board holders and the hooks being integrally formed as a one-piece unitary member, respectively.

7. The board attachment structure according to claim 1, wherein
the board holders are arranged relative to the frame such that the predetermined spacing between the adjacent board holders is dimensioned to correspond to a width of the circuit board.

8. An electric device comprising:
a frame;
a circuit board arranged relative to the frame;
a plurality of board holders detachably coupled to the frame, the board holders holding the circuit board between a pair of adjacent board holders of the board holders, the adjacent board holders being spaced apart from each other with a predetermined spacing therebetween, the adjacent board holders having mutually facing surfaces with grooves, respectively, the grooves of the adjacent board holders extending in a lengthwise direction of the adjacent board holders, the grooves of the adjacent board holders supporting opposite edge portions of the circuit board, respectively; and
a plurality of engagement mechanisms detachably coupling the board holders to the frame, respectively; the engagement mechanisms having engagement holes that are provided to the frame and hooks that are disposed on the board holders, the hooks of the board holders being detachably engaged with the engagement holes of the frame, respectively.

9. The electric device according to claim 8, wherein
each of the board holders has a slender core member with a pair of groove components, the slender core member having a symmetrical shape relative to a center axis of the slender core member, the groove components being disposed in opposite side faces of the slender core member, respectively, at least one of the groove components forming one of the grooves of the adjacent board holders.

10. The electric device according to claim 8, wherein
the frame further includes bulging portions with top faces, the engagement holes of the engagement mechanisms being disposed in the top faces of the bulging portions, respectively.

11. The electric device according to claim 8, wherein
each the adjacent board holders includes one of a convex component and a concave component within each of the grooves of the adjacent board holders, and
the circuit board includes the other of the convex component and the concave component on each of the opposite edge portions of the circuit board, the one of the convex component and the concave component engaging with the other of the convex component and the concave component to position the circuit board relative to the adjacent board holders in the lengthwise direction of the adjacent board holders.

12. The electric device according to claim 8, wherein
the frame is made of a sheet metal, the frame forming a rear chassis of an image display module.

13. The electric device according to claim 8, wherein
the board holders and the hooks are made of resin, the board holders and the hooks being integrally formed as a one-piece unitary member, respectively.

14. The electric device according to claim 8, wherein
the circuit board has a width measured in a direction perpendicular to the lengthwise direction of the adjacent board holders, the width of the circuit board corresponding to the predetermined spacing between the adjacent board holders.

15. The electric device according to claim 8, further comprising
an additional circuit board arranged relative to the frame, the board holders holding the additional circuit board between another pair of adjacent board holders of the board holders.

16. The electric device according to claim 15, wherein
the circuit board has a width measured in a widthwise direction perpendicular to the lengthwise direction of the adjacent board holders, the width of the circuit board corresponding to the predetermined spacing between the adjacent board holders, and
the additional circuit board has a width measured in the widthwise direction, the width of the additional circuit board being equal to the width of the circuit board.

17. The electric device according to claim 15, wherein
the circuit board has a length measured in the lengthwise direction of the adjacent board holders, the length of the circuit board being equal to a length of the additional circuit board measured in the lengthwise direction.

18. The electric device according to claim 15, wherein
the circuit board has a length measured in the lengthwise direction of the adjacent board holders, the length of the circuit board being different from a length of the additional circuit board measured in the lengthwise direction.
